(19) United States
(12) Patent Application Publication
(10) Pub. No.: US 2006/0128093 A1
(43) Pub. Date: Jun. 15, 2006

(54) Method of manufacturing semiconductor device

(76) Inventors: Keiichi Takenaka, Kawasaki-shi (JP); Katsunori Yahashi, Yokohama-shi (JP); Itsuko Sakai, Yokohama-shi (JP); Masaki Narita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/105,465

(22) Filed: Apr. 14, 2005

(30) Foreign Application Priority Data
Dec. 15, 2004 (JP) 2004-362355

(51) Int. Cl. H01L 21/8242

(52) U.S. Cl. 438/243; 438/706

(57) ABSTRACT

A method of manufacturing a semiconductor device is provided. The method comprises forming a mask member on a surface of a semiconductor substrate; and forming a trench in the semiconductor substrate by selectively etching the semiconductor substrate with a mask of the mask member under a certain pressure. The pressure is changed on arrival of (Etching Depth)/(Aperture Width in said surface) at 30 or more for the remainder of the etching by a factor ranging from 1/2 to 9/10 relative to the pressure at the time of the arrival.

### CROSS-REFERENCE TO RELATED APPLICATIONS

This application is based upon and claims the benefit of priority from the prior Japanese Patent Application No. 2004-362355, filed on Dec. 15, 2004; the entire contents of which are incorporated herein by reference.

### BACKGROUND OF THE INVENTION

1. Field of the Invention

The present invention relates to a method of manufacturing a semiconductor device having a trench, such as a method of forming a trench for use in a DRAM (Dynamic Random Access Memory) to bury a capacitor therein.

2. Description of the Related Art

Semiconductor devices such as DRAMs and analog circuits are provided with capacitors. For example, the DRAM is configured to store one bit information based on the amount of charge accumulated in the capacitor. The DRAM inevitably causes leakage of the charge accumulated in the capacitor. Accordingly, it is required to read information once prior to dissipation of the charge from the capacitor and then write the same information. This is called refresh operation. Without a need for excessive refresh operation to store information correctly, the capacitor is required to have a larger capacitance. The capacitance C of the capacitor can be represented by C=εS/d, where ε denotes a dielectric constant of a capacitor insulator or a dielectric film; S denotes a surface area of the capacitor insulator; and d denotes a thickness of the capacitor insulator. Thus, the capacitance C is proportional to the surface area S of the capacitor insulator.

Fine patterning of the DRAM prevents a capacitor formed in planar on the surface of the semiconductor substrate from having a larger surface area of the capacitor insulator that increases the capacitance of the capacitor. Thus, a trench is formed in the semiconductor substrate by etching to bury the capacitor therein to extend the capacitor vertically. This is effective to enlarge the surface area of the capacitor insulator to increase the capacitance of the capacitor.

In the case of the capacitor formed in the trench, a deeper trench ensures the capacitance of the capacitor even if the DRAM is more finely patterned. A larger aspect ratio of the trench (Depth of the trench/Aperture Diameter of the upper end of the trench) makes the etching hard to proceed in the depth of the trench. Accordingly, various methods of forming trenches have been proposed (for example, JP Patent No. 3219149, FIGS. 1, 4-7 and U.S. Pat. No. 6,071,823, FIGS. 5 and 6).

### BRIEF SUMMARY OF THE INVENTION

In an aspect the present invention provides a method of manufacturing a semiconductor device. The method comprises, forming a mask member on a surface of a semiconductor substrate; and forming a trench in the semiconductor substrate by selectively etching the semiconductor substrate with a mask of the mask member under a certain pressure. The pressure is changed on arrival of (Etching Depth)/(Aperture Width in said surface) at 30 or more for the remainder of the etching by a factor ranging from 1/2 to 9/10 relative to the pressure at the time of the arrival.

In another aspect the present invention provides a method of manufacturing a semiconductor device. The method comprises, forming a mask member on a surface of a semiconductor substrate; and forming a trench in the semiconductor substrate by selectively etching the semiconductor substrate with a mask of the mask member under a certain bias power. The bias power is changed on arrival of (Etching Depth)/(Aperture Width in said surface) at 30 or more for the remainder of the etching by a factor ranging from 1.25 to 1.5 relative to the bias power at the time of the arrival.

### BRIEF DESCRIPTION OF THE DRAWINGS

FIG. 1 is a cross-sectional view of memory cells in a DRAM fabricated in a method of manufacturing a semiconductor device according to the embodiment;

FIG. 2 is an equivalent circuit diagram of one memory cell shown in FIG. 1;

FIG. 3 is a schematic of an etching apparatus for use in the method of manufacturing a semiconductor device according to the embodiment;

FIG. 4 shows a first step to the trench formation in the method of manufacturing a semiconductor device according to the embodiment;

FIG. 5 shows a second step to the trench formation;

FIG. 6 shows a third step to the trench formation;

FIG. 7 shows a fourth step to the trench formation;

FIG. 8 shows a fifth step to the trench formation;

FIG. 9 is a cross-sectional view illustrative of a method of forming a lower portion of a trench in accordance with a comparative example;

FIG. 10 shows a first step after the trench formation in the method of manufacturing a semiconductor device according to the embodiment;

FIG. 11 shows a second step after the trench formation;

FIG. 12 shows a third step after the trench formation;

FIG. 13 shows a fourth step after the trench formation;

FIG. 14 shows a fifth step after the trench formation;

FIG. 15 shows a sixth step after the trench formation;

FIG. 16 shows a seventh step after the trench formation;

FIG. 17 shows an eighth step after the trench formation;

FIG. 18 shows a ninth step after the trench formation;

FIG. 19 shows a tenth step after the trench formation;

FIG. 20 shows an eleventh step after the trench formation;

FIG. 21 shows a twelfth step after the trench formation; and

FIG. 22 shows a thirteenth step after the trench formation.

### DETAILED DESCRIPTION OF THE INVENTION

Embodiments of the present invention will now be described with reference to the drawings. In the figures the same reference numerals are given to the parts same as or similar to those once described to avoid duplicate description thereof. The embodiment has a primary characteristic in forming a trench in a semiconductor substrate by selectively etching the semiconductor substrate under a certain pressure. The pressure is changed on arrival of (Etching Depth)/(Aperture Width (Diameter) in a surface of the semiconductor substrate) at 40 or more for the remainder of the etching by a factor ranging from 1/2 to 9/10 relative to the pressure at the time of the arrival.

In the trench formed in accordance with the embodiment, a trench capacitor for a DRAM memory cell is disposed. The following description is given first to a structure of the DRAM memory cell fabricated in a method of manufacturing a semiconductor device according to the embodiment.

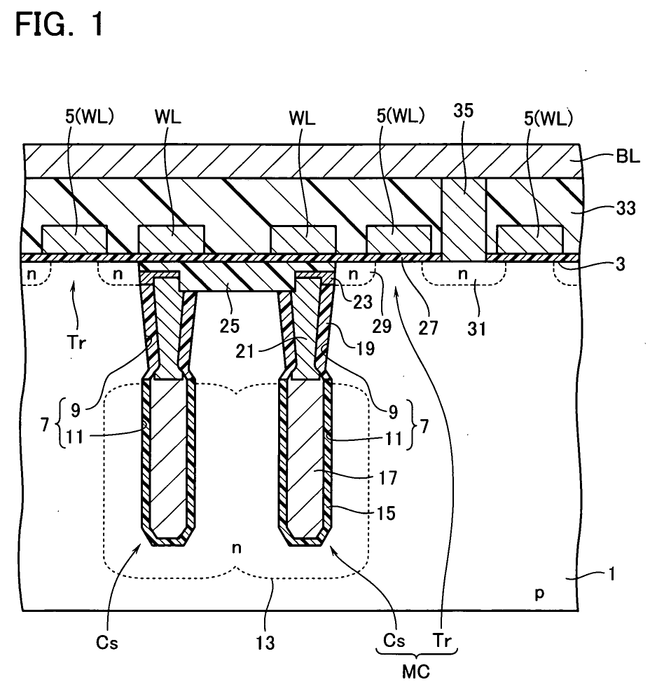

FIG. 1 is a cross-sectional view of memory cells in a DRAM fabricated in the method of manufacturing a semiconductor device according to the embodiment. A memory cell MC comprises a MOS (Metal Oxide Semiconductor) transistor Tr having a gate electrode 5 formed on a surface 3 of a semiconductor substrate 1, and a capacitor Cs formed in the semiconductor substrate 1. The memory cell MC has the following detailed structure.

In the p-type semiconductor substrate (such as a silicon substrate) 1, a plurality of deep trenches 7 are formed so as to extend from the surface 3 to the inside of the semiconductor substrate 1. The trench 7 has a depth of 6-8 μm, for example. The trench 7 has an upper portion 9 above a border set at a depth of 1.3-1.5 μm from the surface 3, for example, and a lower portion 11 below the border. The upper portion 9 has tapered sides such that the trench 7 has a smaller width at the inside of the semiconductor substrate 1 than that at the surface 3. Accordingly, in the upper portion 9 of the trench, the trench 7 has a gradually decreasing width. In contrast, in the lower portion 11 of the trench, the trench 7 has a substantially constant width.

An n-type impurity region 13 is formed in the semiconductor substrate 1 around the lower portion 11 of the trench. A capacitor insulator film 15 is formed on a side of the lower portion 11. A buried conductive member 17 composed of polysilicon is formed on the capacitor insulator film 15 as buried in the lower portion 11. The capacitor Cs includes the impurity region 13 serving as one electrode, the capacitor insulator film 15, and the buried conductive member 17 serving as the other electrode.

A collar insulator film 19 is formed on a side of the upper portion 9 of the trench. The collar insulator film 19 prevents formation of a parasitic transistor. Accordingly, the collar insulator film 19 is thicker than the capacitor insulator film 15. A buried wire 21 is formed on the collar insulator film 19 as buried in the upper portion 9 of the trench. The buried wire 21 is connected to the buried conductive member 17 in the trench 7. A conductive film 23 is formed on the upper portion 9 of the trench to cover the collar insulator film 19 and the buried wire 21 and is in contact with the buried wire 21. A device isolation film 25 is buried in the surface 3 and disposed between adjoining trenches 7.

A gate insulator film 27 for the MOS transistor Tr is formed over the surface 3. Word lines WL are disposed at intervals on the gate insulator. The word line WL located on an active region serves as the gate electrode 5. The active region is defined as a region that includes no device isolation film 25 formed therein. An n-type source region 29 and an n-type drain region 31 are formed in the active region to configure the MOS transistor Tr. The source region 29 is in contact with the conductive film 23.

An interlayer insulator film 33 is formed over the word lines WL. A bit line BL is formed on the interlayer insulator film 33. The bit line BL is connected to the drain region 31 through a connection member 35 buried in the interlayer insulator film 33.

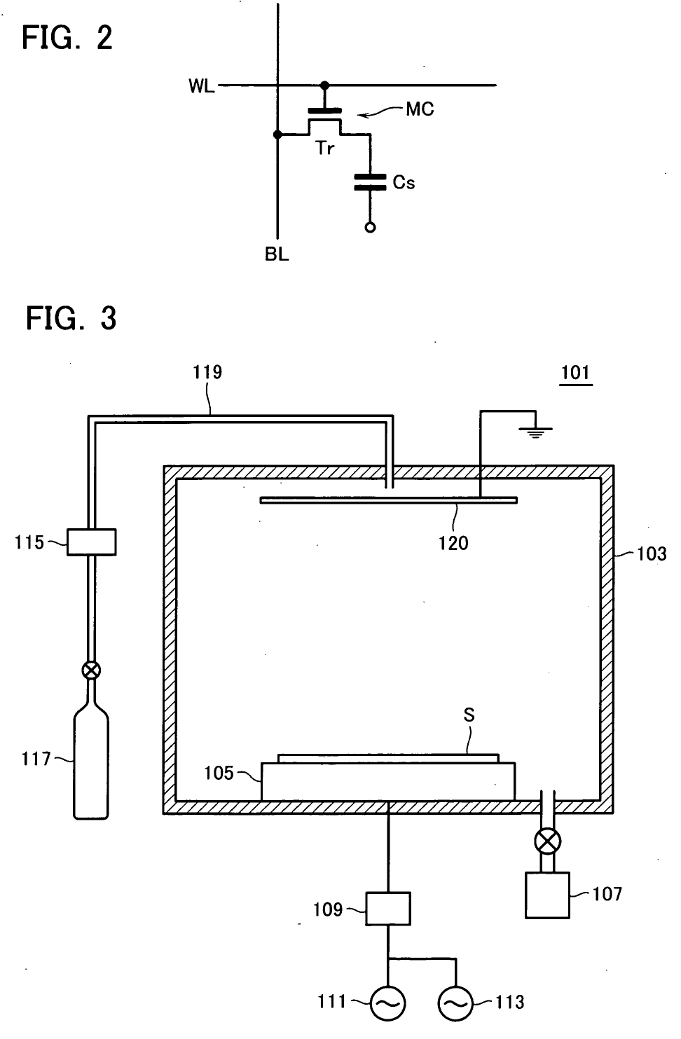

An equivalent circuit of the memory cell MC shown in FIG. 1 is described with reference to FIG. 2. The memory cell MC comprises one MOS transistor Tr and one capacitor Cs. The word line WL is selected to turn on the MOS transistor Tr at the gate, and the bit line BL is selected to define a potential of “H” or “L”. Charge is accumulated into the capacitor Cs in the selected memory cell MC in the case of “H” and released therefrom in the case of “L” to write one bit information.

The following description is given to an etching apparatus for use in the trench formation in the method of manufacturing a semiconductor device according to the embodiment. FIG. 3 is a schematic of the etching apparatus. The etching apparatus 101 comprises a chamber 103, and a stage 105 arranged in the lower portion of the chamber 103 to serve as a cathode electrode. As a semiconductor substrate targeted for trench formation, a wafer S is placed on the stage 105.

The etching apparatus 101 further comprises a vacuum pump 107 operative to adjust pressure in the chamber 103, and two radio-frequency power sources 111, 113 connected to an electrode in the chamber 103 through an impedance matching device or matcher 109. The radio-frequency power source 111 is connected to the stage 105 serving as the cathode electrode to supply a radio-frequency power of 3.2 MHz. The radio-frequency power source 113 is also connected to the stage 105 to supply a radio-frequency power of 40 MHz. The radio-frequency power source 111 supplies the power to the stage 105 at a low frequency as a bias power. The radio-frequency power source 113 on the other hand supplies the power to the stage 105 at a high frequency as a source power. Thus, the etching apparatus 101 operates in a double-frequency superimposition scheme that employs two different frequencies superimposed.

The etching apparatus 101 further comprises a gas conduit 119 having one end led to the upper portion in the chamber 103 and the other end connected through a mass flow 115 to a gas storage bin 117 for etching gas, and an anode electrode 120 grounded and arranged opposite to the stage 105 serving as the cathode electrode.

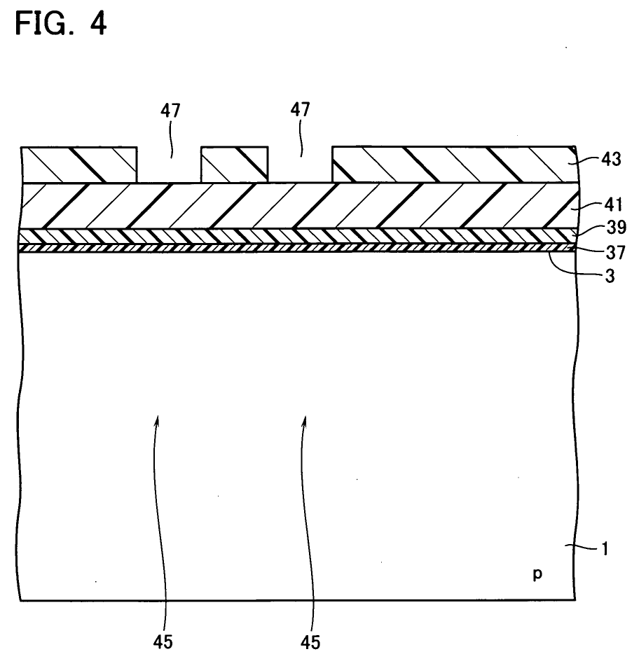

The method of manufacturing a semiconductor device according to the embodiment is described separately about the steps to the trench formation and about the steps thereafter. FIGS. 4-8 show cross-sectional views illustrative of the steps to the trench formation.

As shown in FIG. 4, a silicon oxide film 37 with a thickness of 2 nm is formed by thermal oxidation on the surface 3 of the silicon substrate 1. A silicon nitride film 39 with a thickness of 220 nm is then formed over the silicon oxide film 37 by CVD (Chemical Vapor Deposition). If the silicon nitride film 39 is formed directly over the surface 3, the silicon nitride film 39 can not be brought into intimate contact with the semiconductor substrate 1. Accordingly, the silicon oxide film 37 is interposed therebetween.

A silicon oxide film 41 with a thickness of 1600 nm is then formed by CVD over the silicon nitride film 39. A spin coating method is employed to form a film of resist 43 with a thickness of 600 nm over the silicon oxide film 41. A process of photolithography is applied to pattern the resist 43 such that the resist 43 has an aperture 47 at the position corresponding to a region 45 for formation of the trench 7.

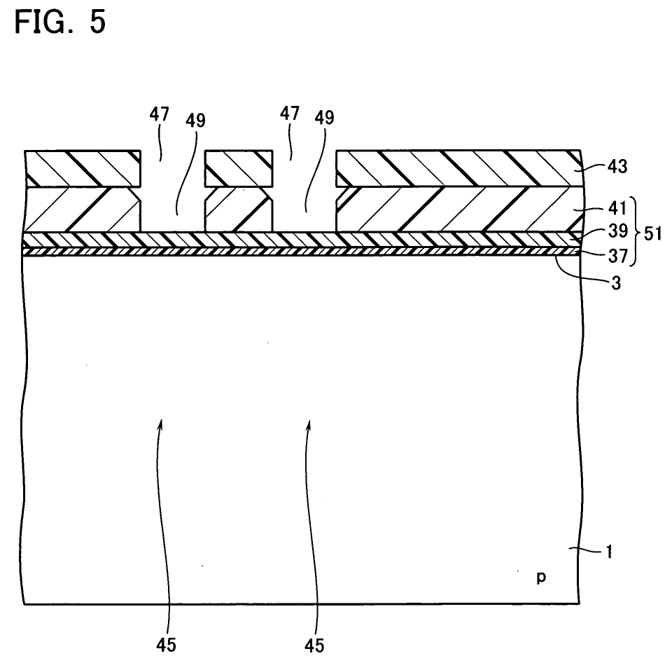

As shown in FIG. 5, with a mask of the patterned resist 43, an isotropic etching such as wet etching is applied to selectively remove the upper portion of the silicon oxide film 41. Then, an anisotropic etching such as RIE (Reactive Ion Etching) is employed to etch the remainder of the silicon oxide film 41, the silicon nitride film 39, and the silicon oxide film 37 to make the surface 3 exposed. Thus, the silicon oxide film 41, the silicon nitride film 39 and the silicon oxide film 37 form a mask member 51 having an aperture 49 that makes the surface 3 exposed. The wafer S containing the semiconductor substrate 1 after removal of the resist 43 is mounted on the stage 105 as shown in FIG. 3.

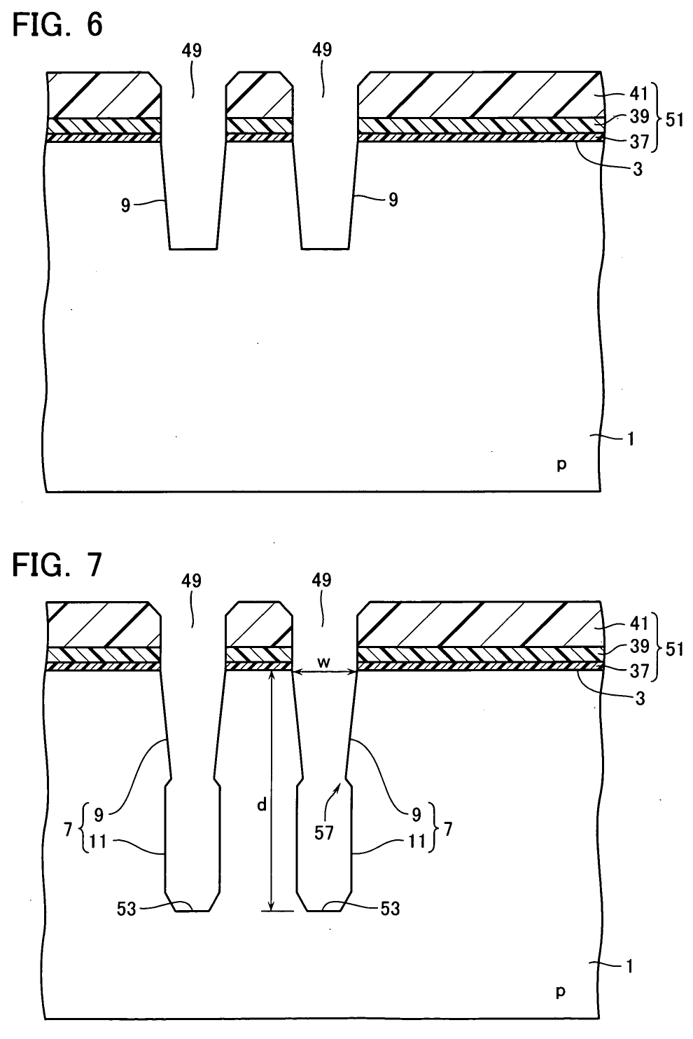

As shown in FIG. 6, with a mask of the mask member 51, RIE is applied to selectively etch into the semiconductor substrate 1 to a depth of about 1.5 μm to form the upper portion 9 of the trench. The upper portion 9 of the trench has tapered sides such that the width of the trench gradually decreases as extending from the surface 3 toward the inside of the semiconductor substrate 1. The etching is given the following specific conditions. The etching gas is a mixed gas containing 230 sccm of HBr, 21 sccm of 02 and 35 sccm of NF₃. The chamber 103 of FIG. 3 has an internal pressure of 150 mTorr. The source power is set at 700 W and the bias power is set at 450 W.

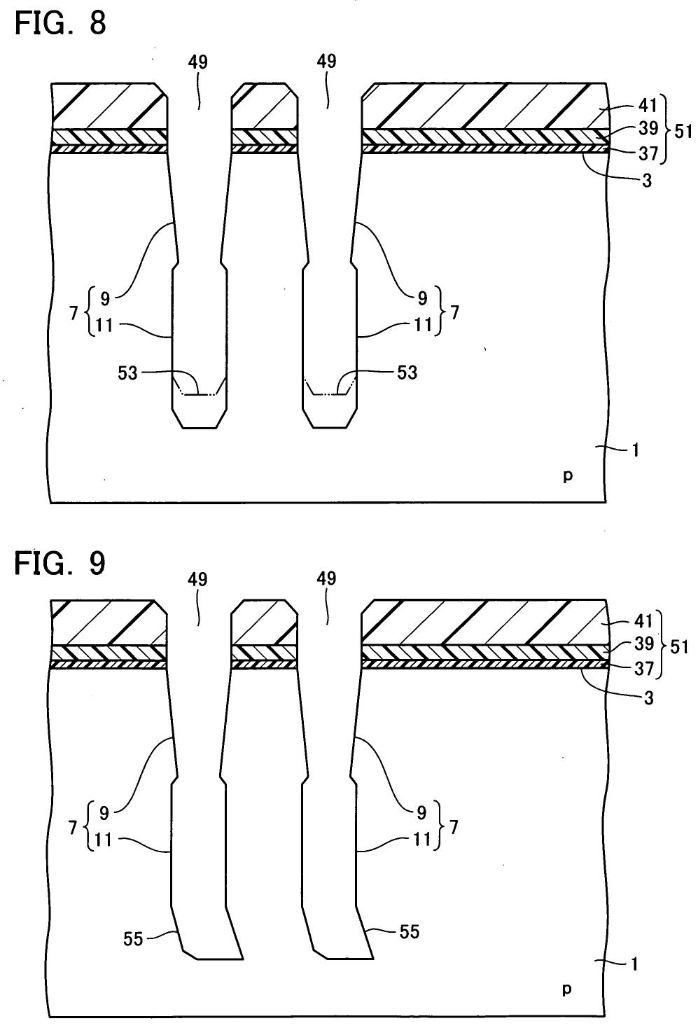

After formation of the upper portion 9 of the trench, the process is transferred to the step of forming the lower portion 11 of the trench with the use of RIE as shown in FIGS. 7 and 8. The lower portion 11 has a substantially constant width along the depth. The steps of forming the lower portion 11 of the trench are divided into the step before arrival of (Etching Depth d)/(Aperture Width w in the surface 3) at 40 (the former step as shown in FIG. 7) and the step thereafter (the latter step as shown in FIG. 8). The pressure inside the chamber 103 is reduced in the latter step relative to the former step for the following reason, which is described using a comparative example. The etching depth d is defined as a length from the original surface 3 to a currently etched surface 53. In the embodiment the arrival of (Etching Depth d)/(Aperture Width w in the surface 3) at 40 occurs when the etching depth d reaches 6.8 μm and the aperture width w reaches 170 nm, for example.

FIG. 9 is a cross-sectional view illustrative of a method of forming the lower portion 11 of the trench in accordance with the comparative example, which corresponds to FIG. 8. RIE is a scheme for etching with ions generated from an etching gas. If the pressure inside the chamber 103 is not changed through the formation of the lower portion 11 of the trench, the straightness of traveling ions is worsened on arrival of (Etching Depth d)/(Aperture Width w in the surface 3) at approximately 42-43. This makes it difficult to control the shape of the trench 7 and accordingly bents a portion 55 of the trench deeper than that at the time of the arrival. Once the bent portion 55 of the trench is formed, the surface area of the capacitor insulator varies greatly and the bent portion 55 of the trench is hardly covered with a uniform thick capacitor insulator due to the low controllability of the shape during formation of the capacitor Cs. Thus, a highly reliable capacitor Cs can not be formed.

In the embodiment the former step and the latter step are divided on arrival of (Etching Depth d)/(Aperture Width w in the surface 3) at 40 as a border, immediately before the arrival at approximately 42-43. In the latter step, the pressure inside the chamber 103 is changed for further etching by a factor ranging from 1/2 to 9/10 relative to that in the former step. In other words, the pressure is changed on arrival of (Etching Depth d)/(Aperture Width w in the surface 3) at 40 for the remainder of the etching by a factor ranging from 1/2 to 9/10 relative to the pressure at the time of the arrival. This is effective to retain the straightness of traveling ions and prevent the bend of the trench 7.

The pressure is changed by 1/2 or more because, if less than 1/2, the selective etching ratio between the mask member 51 and the semiconductor substrate 1 becomes too small to form the trench 7 with a desired depth. On the other hand, the pressure is changed by 9/10 or less because, if more than 9/10, reacted products yielded by etching at the deepest portion in the trench 7 are hardly exhausted to external. As a result, the reacted products present in the deepest portion have a lowered uniformity, which causes the above-described bent portion 55 of the trench 7 consequently. Preferably, the pressure inside the chamber 103 at the former step is equal to 180 mTorr or higher from the viewpoint of a selective etching ratio sufficiently ensured between the mask member 51 and the semiconductor substrate 1 to form a deep trench 7 with (Etching Depth d)/(Aperture Width w in the surface 3) more than 40.

The specific conditions for the former step shown in FIG. 7 are described. The etching gas is a mixed gas containing 230 sccm of HBr, 8 sccm of O₂ and 17 sccm of NF₃. Another F-series gas not containing carbon may be employed instead of NF₃. For example, a mixed gas of HBr, O₂ and SF₆ may be employed. For etching the semiconductor substrate 1 at a high selective ratio to the mask member 51, the pressure inside the chamber 103 is kept at 200 mTorr, for example. In addition, the source power is set at 800 W and the bias power is set at 900 W, for example. In the former step of etching, the width of the lower portion 11 of the trench is extended wider than that of the upper portion 9 of the trench at the connection 57 of the upper portion 9 of the trench with the lower portion 11 of the trench.

On arrival of (Etching Depth d)/(Aperture Width w in the surface 3) at 40, as shown in FIG. 8, the pressure inside the chamber 103 is changed from 200 mTorr to 150 mTorr (that is, a value equal to 3/4 of 200 mTorr) for the remainder of etching to complete the lower portion 11 of the trench.

As described above, in the method of manufacturing a semiconductor device according to the embodiment, the bent portion 55 (FIG. 9) is not formed at the substantially constant wide lower portion 11 of the trench. Rather, the lower portion 11 of the trench can be formed substantially perpendicular to the surface 3. If the pressure inside the chamber 103 is set at 200 mTorr in the former step, the pressure inside the chamber 103 may be set within a range between 135 mTorr and 180 mTorr in the latter step. In this case, the effect for preventing formation of the bent portion 55 at the lower portion 11 of the trench is more remarkable than when the pressure falls outside the range.

In the embodiment, considering that the trench 7 begins to bend at about 42-43 of (Etching Depth d)/(Aperture Width w in the surface 3), the pressure inside the chamber 103 is changed at 40 as a border, which appears immediately before those. Even if the pressure inside the chamber 103 is changed on arrival at 30 or more, the formation of the bent portion 55 at the lower portion 11 of the trench can be prevented. Nevertheless, the trench 7 can be formed deeper if the pressure inside the chamber 103 is changed at a value close to 40 of (Etching Depth d)/(Aperture Width w in the surface 3).

If the trench 7 begins to bend at much more than 42-43 of (Etching Depth d)/(Aperture Width w in the surface 3), the pressure inside the chamber may be changed at a value less than such one that appears immediately before the beginning of the bend.

Instead of changing the pressure inside the chamber 103 between the former and latter steps, the bias power in the latter step may be changed by a factor ranging from 1.25 to 1.5 relative to that in the former step. Even in this case, it is also possible to retain the straightness of traveling ions to achieve the effect for preventing the bend of the trench 7. The bias power is changed by 1.25 or more because, if less than 1.25, the straightness of traveling ions is worsened at the deepest portion in the trench 7 and the shape of the trench 7 can not be controlled. The bias power is changed by 1.5 or less on the other hand because, if more than 1.5, the selective etching ratio between the mask member 51 and the semiconductor substrate 1 becomes too small to form the trench 7 with a desired depth. Preferably, the bias power in the former step is kept at 1000 W or less to ensure a sufficient selective etching ratio between the mask member 51 and the semiconductor substrate 1 to form a deep trench 7 with (Etching Depth d)/(Aperture Width w in the surface 3) more than 40.

The specific conditions in the case of changing the bias power are described. In both the former and latter steps, the etching gas is a mixed gas containing 230 sccm of HBr, 8 sccm of O₂ and 17 sccm of NF₃. The chamber 103 has an internal pressure of 200 mTorr, for example. The source power is kept at 800 W, for example. The bias power in the former step is set at 900 W while the bias power in the latter step is set at 1200 W (about 1.3 times).

If the bias power in the former step is set at 900 W, the bias power in the latter step may be set in a range between 1150 W and 1350 W. In this case, the effect for preventing formation of the bent portion 55 at the lower portion 11 of the trench is more remarkable than when the bias power falls outside the range.

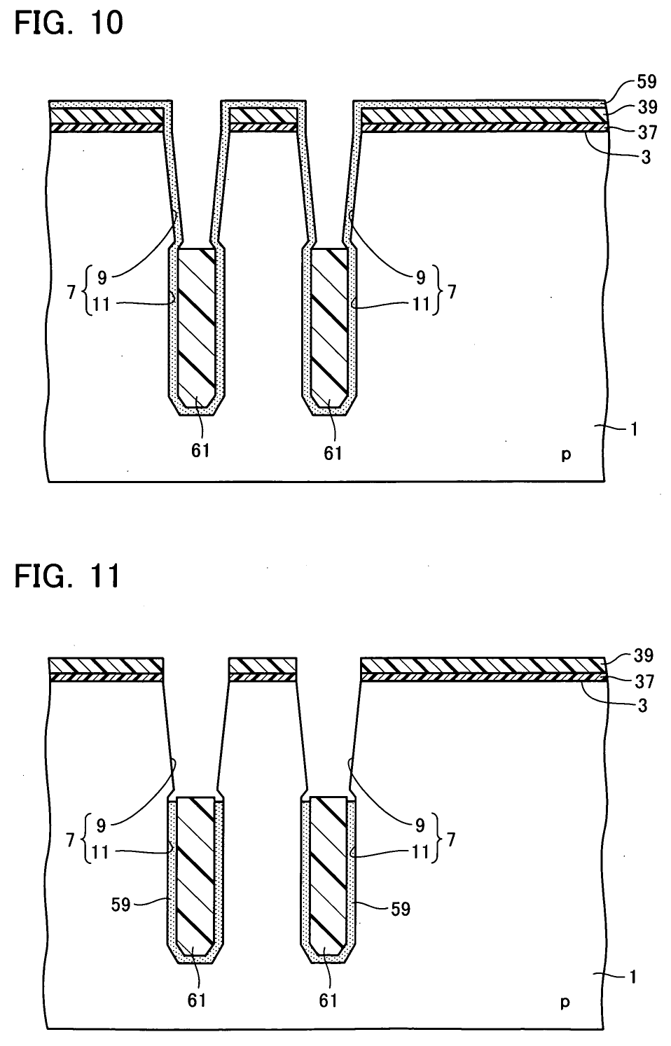

Finally, the steps after the trench formation are described. FIGS. 10-22 show cross-sectional views sequentially illustrative of the steps after the trench formation. As shown in FIG. 10, the silicon oxide film 41 is removed. A method of CVD is employed to form an impurity-containing film such as an AsSG film 59 over the entire surface of the semiconductor substrate 1. Thus, the AsSG film 59 is formed on a side of the trench 7. The AsSG film 59 has a thickness of about 30 nm.

A spin coating method is then employed to form a film of resist 61 with a thickness of several 1000 nm over the entire surface of the semiconductor substrate 1. The resist 61 is buried in the trench 7. A down-flow etching is applied to remove the resist 61 formed on the silicon nitride film 39 and in the upper portion 9 of the trench 7 therefrom to make the AsSG film 59 exposed. The resist 61 is left in the lower portion 11 of the trench 7.

As shown in FIG. 11, a wet etching or down-flow etching of hydrofluoric acid series is applied to remove the AsSG film 59 formed on the silicon nitride film 39 and on the side of the upper portion 9 of the trench 7 therefrom. A wet etching with a mixed solution of aqueous hydrogen peroxide and sulfuric acid is employed to remove the resist 61 left in the lower portion 11 of the trench 7 therefrom.

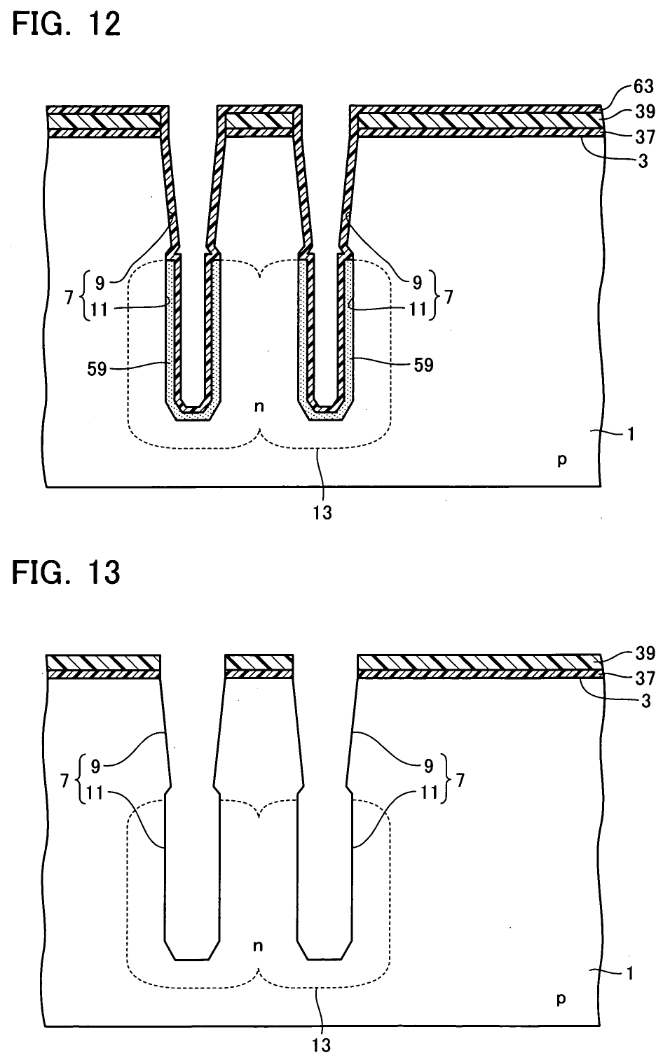

As shown in FIG. 12, CVD is applied to form a TEOS (tetraethyl orthosilicate) film 63 over the entire surface of the semiconductor substrate 1 so as to cover the side of the trench 7 therewith. A process of thermal diffusion is applied at about 1000° C. to diffuse As contained in the AsSG film 59 therefrom into the semiconductor substrate 1 around the lower portion 11 of the trench 7 to form the n-type impurity region 13 that serves as one electrode of the capacitor. The presence of the TEOS film 63 prevents As from diffusing into the semiconductor substrate 1 around the upper portion 9 of the trench 7. A wet etching of hydrofluoric acid series is applied to remove the TEOS film 63 and the AsSG film 59 as shown in FIG. 13.

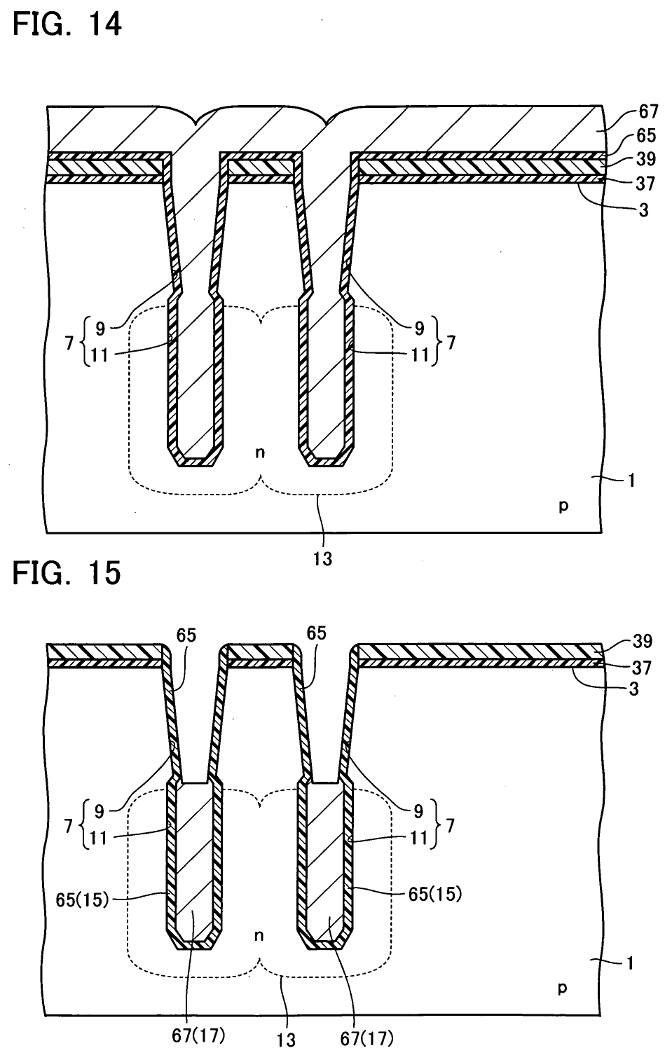

As shown in FIG. 14, CVD is applied to form an insulator film 65 with a thickness of several nm over the entire surface of the semiconductor substrate 1 so as to form the insulator film 65 on the side of the trench 7. The insulator film 65 serves as the capacitor insulator film. A NO film that is a layered film of nitride and oxide films, and a dielectric film other than that may be employed as the insulator film 65. Then, CVD is employed to form a conductive film 67 with a thickness of several 100 nm over the entire surface of the semiconductor substrate 1 so as to fill the trench 7 therewith. A film of As-doped polysilicon may be employed as the conductive film 67.

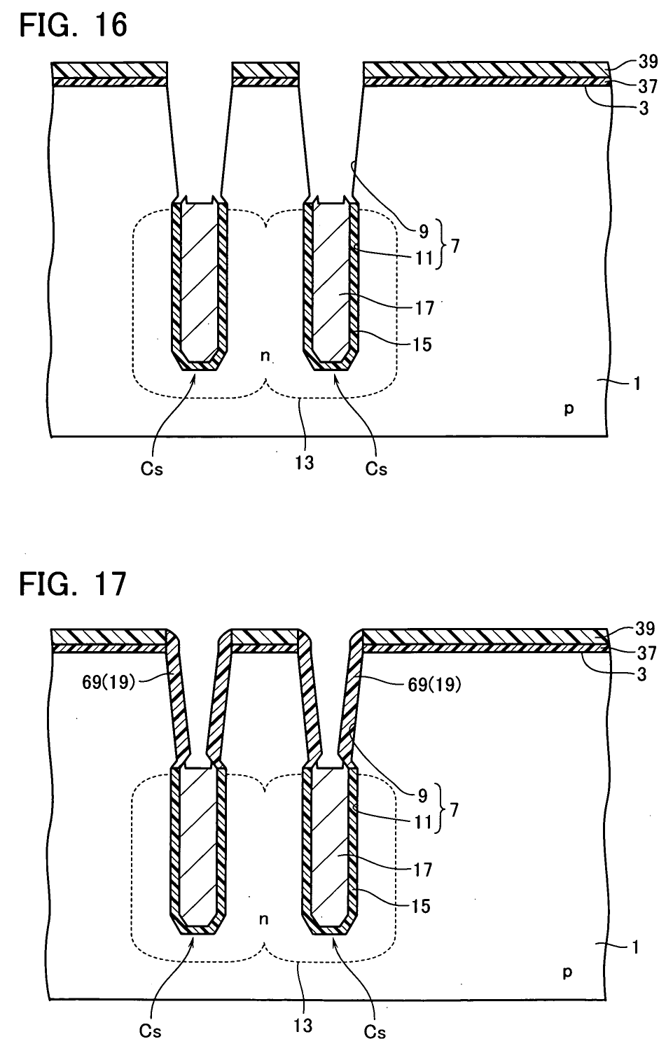

As shown in FIG. 15, a certain planarization process such as CMP (Chemical Mechanical Polishing) and a certain etching step is applied to remove the conductive film 67 such as to leave the conductive film 67 in the lower portion 11 of the trench. The conductive film 67 left in the lower portion 11 of the trench serves as the other electrode of the capacitor, or the buried conductive member 17. The insulator film 65 located between the buried conductive member 17 and the lower portion 11 of the trench serves as the capacitor insulator film 15. A wet etching of phosphoric acid series is employed next to remove the insulator film 65 formed on the side of the upper portion 9 of the trench therefrom as shown in FIG. 16.

As shown in FIG. 17, CVD is employed to form a TEOS film 69 over the entire surface of the semiconductor substrate 1. RIE is applied to etch off the TEOS film 69 entirely except for the TEOS film 69 left on the side of the upper portion 9 of the trench, which serves as the collar insulator film 19 in FIG. 1. The collar insulator film 19 prevents formation of a parasitic transistor and accordingly requires a sufficient thickness. Thus, the thickness of the collar insulator film 19 (for example, 25-35 nm) is determined larger than the thickness of the capacitor insulator film 15 (for example, 4-6 nm).

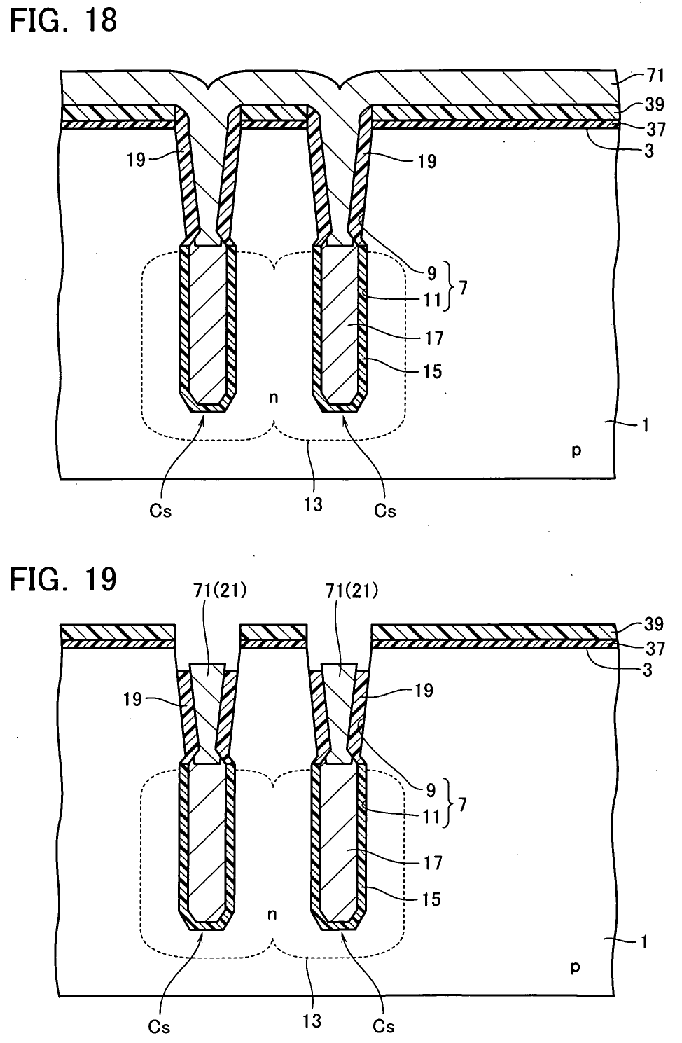

As shown in FIG. 18, CVD is employed to form a conductive film 71 with a thickness of several 100 nm over the entire surface of the semiconductor substrate 1 so as to fill the upper portion 9 of the trench therewith. A film of As-doped polysilicon may be employed as the conductive film 71.

As shown in FIG. 19, CMP and a certain etching step are applied to remove the conductive film 71 from the upper portion 9 of the trench into a certain depth. The conductive film 71 left in the upper portion 9 of the trench serves as the buried wire 21. The etching makes a portion of the collar insulator film 19 exposed. The exposed collar insulator film 19 is removed using a wet etching of phosphoric acid series.

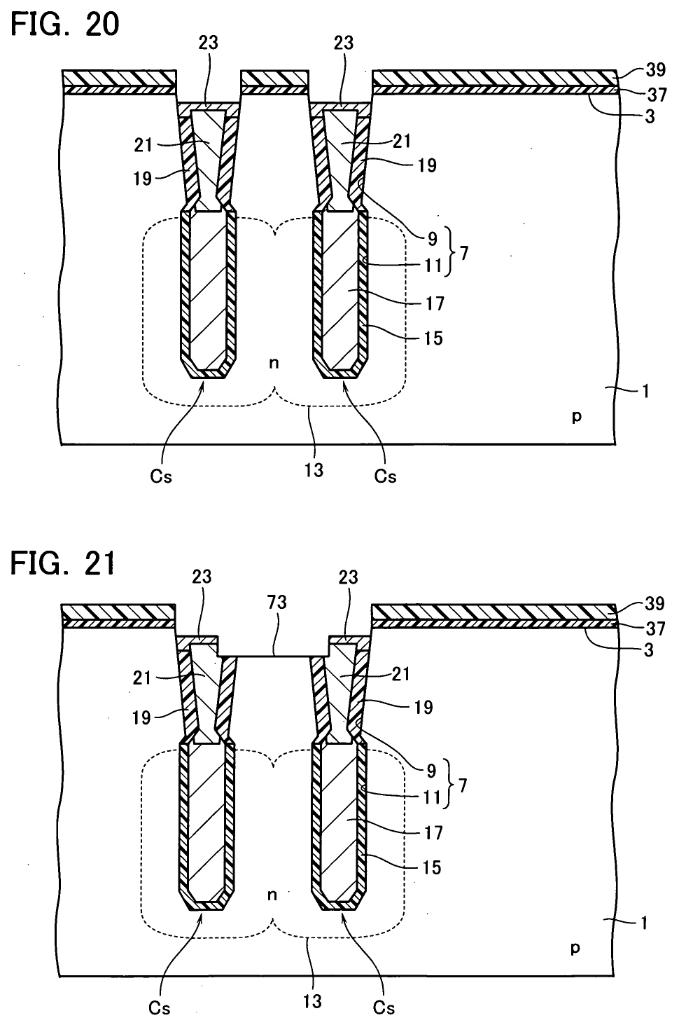

As shown in FIG. 20, CVD is employed to form the conductive film 23 with a thickness of several 100 nm over the entire surface of the semiconductor substrate 1. CMP, for example, is applied to remove the conductive film 23 into a depth that makes the side of the upper portion 9 of the trench exposed partly.

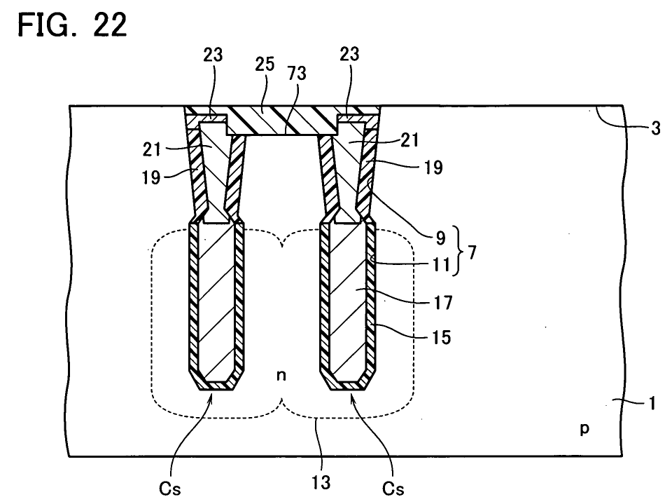

As shown in FIG. 21, a shallow trench 73 is formed between adjoining trenches 7 as spanning from one to the other thereof. Then, CVD is applied to form an insulator film (such as TEOS film) with a thickness of several 100 nm over the entire surface of the semiconductor substrate 1 as shown in FIG. 22. CMP, for example, is applied to remove the above-described insulator film formed on the surface 3 therefrom to form the device isolation film 25 in the trench 73. Thereafter, the publicly known methods are employed to form the MOS transistors Tr, the word lines WL, the bit lines BL and others to complete the memory cells MC according to the embodiment shown in FIG. 1.

Not only the capacitor in the DRAM, but also a capacitor in an analog circuit may be disposed in the trench that is formed in accordance with the embodiment.

What is claimed is:

1. A method of manufacturing a semiconductor device, comprising:
forming a mask member on a surface of a semiconductor substrate; and
forming a trench in said semiconductor substrate by selectively etching said semiconductor substrate with a mask of said mask member under a certain pressure, said pressure being changed on arrival of (Etching Depth)/(Aperture Width in said surface) at 30 or more for the remainder of said etching by a factor ranging from 1/2 to 9/10 relative to said pressure at the time of said arrival.

2. The method of manufacturing a semiconductor device according to claim 1, wherein said arrival of (Etching Depth)/(Aperture Width in said surface) at 30 or more includes arrival at 40 or more.

3. The method of manufacturing a semiconductor device according to claim 1, wherein said forming a trench includes:
forming an upper portion of said trench, said upper portion having tapered sides such that said trench has a smaller width at the inside of said semiconductor substrate than that at said surface; and
forming a lower portion of said trench having a substantially constant width after forming said upper portion of said trench,
wherein said arrival of (Etching Depth)/(Aperture Width in said surface) at 30 or more occurs during said forming a lower portion of said trench.

4. The method of manufacturing a semiconductor device according to claim 3, wherein said forming a lower portion of said trench includes extending the width of said lower portion of said trench wider than said upper portion of said trench at a connection of said upper portion of said trench with said lower portion of said trench.

5. The method of manufacturing a semiconductor device according to claim 1, wherein said pressure is changed prior to said trench being formed bent during said forming a trench.

6. The method of manufacturing a semiconductor device according to claim 3, after said forming a trench, further comprising:
forming an impurity region serving as one electrode of a capacitor in said semiconductor substrate around said lower portion of said trench;
forming a capacitor insulator film on a side of said lower portion of said trench;
forming a buried conductive member serving as the other electrode of said capacitor on said capacitor insulator film as buried in said lower portion of said trench;
forming a collar insulator film on a side of said upper portion of said trench; and
forming a buried wire on said collar insulator film as buried in said upper portion of said trench, said buried wire being connected to said buried conductive member in said trench.

7. The method of manufacturing a semiconductor device according to claim 1, wherein said trench has a depth of 6-8 μm.

8. The method of manufacturing a semiconductor device according to claim 1, wherein a mixed gas is used as an etching gas, which includes HBr, O₂ and an F-series gas not containing carbon.

9. The method of manufacturing a semiconductor device according to claim 1, wherein said pressure at the time of said arrival at 30 or more is equal to 180 mTorr or higher.

10. A method of manufacturing a semiconductor device, comprising:
forming a mask member on a surface of a semiconductor substrate; and
forming a trench in said semiconductor substrate by selectively etching said semiconductor substrate with a mask of said mask member under a certain bias power, said bias power being changed on arrival of (Etching Depth)/(Aperture Width in said surface) at 30 or more for the remainder of said etching by a factor ranging from 1.25 to 1.5 relative to said bias power at the time of said arrival.

11. The method of manufacturing a semiconductor device according to claim 10, wherein said arrival of (Etching Depth)/(Aperture Width in said surface) at 30 or more includes arrival at 40 or more.

12. The method of manufacturing a semiconductor device according to claim 10, wherein said forming a trench includes:
forming an upper portion of said trench, said upper portion having tapered sides such that said trench has a smaller width at the inside of said semiconductor substrate than that at said surface; and
forming a lower portion of said trench having a substantially constant width after forming said upper portion of said trench,
wherein said arrival of (Etching Depth)/(Aperture Width in said surface) at 30 or more occurs during said forming a lower portion of said trench.

13. The method of manufacturing a semiconductor device according to claim 12, wherein said forming a lower portion of said trench includes extending the width of said lower portion of said trench wider than said upper portion of said trench at a connection of said upper portion of said trench with said lower portion of said trench.

14. The method of manufacturing a semiconductor device according to claim 10, wherein said bias power is changed prior to said trench being formed bent during said forming said trench.

15. The method of manufacturing a semiconductor device according to claim 12, after said forming a trench, further comprising:
forming an impurity region serving as one electrode of a capacitor in said semiconductor substrate around said lower portion of said trench;
forming a capacitor insulator film on a side of said lower portion of said trench;
forming a buried conductive member serving as the other electrode of said capacitor on said capacitor insulator film as buried in said lower portion of said trench;
forming a collar insulator film on a side of said upper portion of said trench; and
forming a buried wire on said collar insulator film as buried in said upper portion of said trench, said buried wire being connected to said buried conductive member in said trench.

16. The method of manufacturing a semiconductor device according to claim 10, wherein said trench has a depth of 6-8 μm.

17. The method of manufacturing a semiconductor device according to claim 10, wherein a mixed gas is used as an etching gas, which includes HBr, O₂ and an F-series gas not containing carbon.

18. The method of manufacturing a semiconductor device according to claim 10, wherein said bias power at the time of said arrival at 30 or more is equal to 1000 W or lower.

19. The method of manufacturing a semiconductor device according to claim 10, wherein said etching is executed in a double-frequency superimposition scheme that employs two different frequencies superimposed.

20. The method of manufacturing a semiconductor device according to claim 19, wherein said double-frequency superimposition scheme is operative to generate said bias power at a relatively low radio-frequency, and generate a source power at a relatively high radio-frequency.
